(19) United States
(12) Patent Application Publication
(10) Pub. No.: US 2026/0229853 A1
(43) Pub. Date: Aug. 6, 2026

(54) SUB-MODULE

(71) Applicant: LS ELECTRIC CO., LTD., Anyang-si, Gyeonggi-do (KR)

(72) Inventors: Jin Hee LEE, Anyang-si, Gyeonggi-do (KR); Dae Chul KANG, Anyang-si, Gyeonggi-do (KR)

(21) Appl. No.: 19/158,334

(22) PCT Filed: Feb. 7, 2024
(86) PCT No.: PCT/KR2024/001838

§ 371 Date: Aug. 20, 2025

(30) Foreign Application Priority Data
Mar. 8, 2023 (KR) 10-2023-0030769

(51) Int. Cl. H02B 1/28; H02B 1/20; H02B 1/30; H02M 1/32; H02M 7/00

(52) U.S. Cl. CPC H02B 1/28; H02B 1/20; H02B 1/30; H02M 1/327; H02M 7/003

(57) ABSTRACT

A sub-module is disclosed. The sub-module, according to one aspect of the present disclosure, comprises: an IGBT which is connected to an external power source or load in an electrically conductive manner and of which a surface in one direction has a greater surface area than a surface in another direction; a heat-dissipating member coupled to one surface of the IGBT in the one direction, so as to cool the heat generated by the IGBT; and a capacitor member which is connected to the IGBT in an electrically conductive manner and is arranged to face the other surface of the IGBT in the one direction, wherein the heat-dissipating member comprises a heat-dissipating body coupled to the one surface of the IGBT in the one direction.

### CROSS-REFERENCE TO RELATED APPLICATION

This application is the national phase entry of International Application No. PCT/KR2024/001838, filed on Feb. 7, 2024, which is based upon and claims priority to Korean Patent Application No. 10-2023-0030769, filed on Mar. 8, 2023, the entire contents of which are incorporated herein by reference.

### FIELD

The present disclosure relates to a sub-module, and more particularly, to a sub-module having a structure that can maintain explosion-proof performance while being reduced in size.

### BACKGROUND

A flexible AC transmission system (FACTS) is an operational technology that increases the flexibility of an AC power grid by introducing power electronic control technology into the power transmission system.

Specifically, a flexible AC transmission system can control transmission power by using power semiconductor switching devices. Such a flexible AC transmission system can maximize the utilization of transmission line facilities, increase transmission capacity, and minimize voltage fluctuations.

In a flexible AC transmission system, the storage and input/output of power are achieved by a capacitor element. The capacitor element can be controlled by a switching device. Specifically, the switching device can control the input and output of current to and from the capacitor element.

Generally, the switching device is provided as an insulated gate bipolar transistor (IGBT), which is a semiconductor power electronic device. The IGBT is communicably connected to a control board, which is provided as a printed circuit board or the like. The control board calculates a large amount of control information and controls the capacitor element based on the calculated control information.

When the flexible AC transmission system operates, the IGBT performs high-speed switching operations to apply or block electrical conduction between the control board and the capacitor element.

Therefore, as the operation of the flexible AC transmission system continues, the IGBT generates a large amount of heat. In this case, if an appropriate heat dissipation process is not performed, an explosion of the IGBT may occur.

In addition, considering that the IGBT is a sensitive semiconductor device, it may explode due to external impact or malfunction or the like even without overheating. If the IGBT explodes, various components constituting the IGBT may become debris from the explosion and potentially damage the sub-module forming part of the flexible AC transmission system.

Accordingly, the sub-module is generally provided with an explosion-proof structure to prevent damage to other components or to prevent scattering of the IGBT in the event of an IGBT explosion.

Referring to FIGS. 17 and 18, an example of a sub-module 1000 according to the related art is illustrated. The sub-module 1000 includes a power assembly 1100, which is electrically connected to an external source, and a capacitor assembly 1200, which is electrically connected to the power assembly 1100 and stores power.

The power assembly 1100 includes an IGBT part 1110 that functions as a switching device, a busbar part 1130 that electrically connects the IGBT part 1110 to an external source, and a cover part 1140 that covers these components. In addition, an explosion-proof part 1120 is provided between the IGBT part 1110 and the busbar part 1130 to prevent scattering in the event of an explosion of the IGBT part 1110.

In this case, the inclusion of the explosion-proof part 1120 may increase the overall volume of the sub-module 1000, potentially reducing the advantage of being provided in a modular form.

In addition, in order for the explosion-proof part 1120 to be coupled with the IGBT part 1110, the busbar part 1130, and the cover part 1140, additional fastening components such as screws or rivets are required. This not only increases manufacturing costs and time but also increases the number of components that require assembly, thereby raising the possibility of assembly defects.

Korean Patent Laid-Open Publication No. 10-2019-0109884 discloses a double explosion-proof wall. Specifically, it discloses a double explosion-proof wall comprising a first explosion-proof wall installed on the outside, a second explosion-proof wall installed on the inside, and an insertion pipe module positioned in the space formed between the two walls. The prior art describes an effect in which, when explosive pressure is transmitted to the second explosion-proof wall, the insertion pipe module slides to minimize the impact transmitted to the first explosion-proof wall.

However, this type of double explosion-proof wall is suitable for application to large-scale structures, but it has limitations when applied to small structures such as sub-modules. That is, the double explosion-proof wall disclosed in the prior art requires the insertion pipe module to be placed between the first and second explosion-proof walls, which makes it difficult to manufacture in a compact form.

Korean Registered Patent No. 10-1871410 discloses a power supply device. Specifically, it discloses a power supply device configured in the form of an explosion-proof module, in which a controller for controlling a plurality of switches is integrally assembled with a voltmeter and an ammeter.

However, this type of power supply device only provides a solution for easily replacing the controller in the event of an explosion of a switching device or the like, which is a limitation. That is, the above-described prior art fails to provide a measure to prevent damage to other surrounding devices when a switching device or the like explodes.
Korean Patent Laid-Open Publication No. 10-2019-0109884 (2019 Sep. 27.)
Korean Registered Patent No. 10-1871410 (2018 Jun. 18.)

### SUMMARY

The present disclosure is to solve the above problems, and the present disclosure is directed to providing a sub-module having a structure capable of improving explosion-proof performance.

The present disclosure is also directed to providing a sub-module having a structure capable of being miniaturized.

The present disclosure is also directed to providing a sub-module having a structure that enables ease of manufacturing.

The present disclosure is also directed to providing a sub-module having a structure capable of reducing manufacturing costs.

The problems of the present disclosure are not limited to those mentioned above, and other problems not mentioned will be clearly understood by those of ordinary skill in the art from the following description.

According to an aspect of the present disclosure, provided is a sub-module, comprising an insulated gate bipolar transistor (IGBT) that is electrically connectable to an external power source or load and has a surface area in one direction greater than that of a surface in another direction; a heat-dissipating member coupled to one surface of the IGBT in the one direction to cool heat generated from the IGBT; and a capacitor member that is electrically connected to the IGBT and is disposed to face the other surface of the IGBT in the one direction, wherein the heat-dissipating member includes a heat-dissipating body coupled to the one surface of the IGBT in the one direction; a heat-dissipating support part that continuously extends between the heat-dissipating body and the capacitor member and is coupled to each of the heat-dissipating body and the capacitor member; and an IGBT-accommodating part that is defined by being partially surrounded by the heat-dissipating body and the capacitor member, and accommodates the IGBT.

In this case, a sub-module may be provided in which the heat-dissipating body has a surface, which faces the IGBT, the surface area of which is greater than that of the one surface of the IGBT in the one direction.

In addition, a sub-module may be provided in which a plurality of IGBTs are provided, the plurality of IGBTs being spaced apart from one another in a width direction and a length direction of the heat-dissipating body, and the heat-dissipating body is formed to cover all of the plurality of IGBTs along the one direction.

In this case, a sub-module may be provided in which the sub-module further includes a busbar member that is accommodated in the IGBT-accommodating part and electrically connected to each of the IGBT and the capacitor member, wherein the capacitor member includes a capacitor body that is coupled to the heat-dissipating support part and surrounds the IGBT-accommodating part from one side; and a capacitor terminal that is coupled to the capacitor body and electrically coupled to the busbar member.

In addition, a sub-module may be provided in which the busbar member includes an input busbar that is electrically coupled to each of the IGBT and an external power source or load; and an output busbar that is electrically coupled to each of the IGBT and the capacitor terminal.

In this case, a sub-module may be provided in which a plurality of IGBTs are provided, the plurality of IGBTs being spaced apart from one another in a width direction and a length direction of the heat-dissipating body, and the input busbar includes a first input busbar that is electrically coupled to some of the plurality of IGBTs and to an external power source or load, respectively; and a second input busbar that is spaced apart from the first input busbar and is electrically coupled to the other some of the plurality of IGBTs and to an external power source or load, respectively.

In addition, a sub-module may be provided in which the second input busbar is disposed closer to the capacitor member along the one direction than the first input busbar, and the busbar member includes a support member that is positioned between the other surface of the IGBT and the second input busbar and is electrically coupled to each of the IGBT and the second input busbar.

In this case, a sub-module may be provided in which a plurality of IGBTs are provided, the plurality of IGBTs being spaced apart from one another in a width direction and a length direction of the heat-dissipating body, a plurality of capacitor terminals are provided, the plurality of capacitor terminals being spaced apart from one another in the width direction of the heat-dissipating body, and the output busbar includes a first output busbar that is electrically coupled to some of the plurality of IGBTs and to one of the plurality of capacitor terminals, respectively; and a second output busbar that is electrically coupled to the other some of the plurality of IGBTs and to another one of the plurality of capacitor terminals, respectively.

In addition, a sub-module may be provided in which the output busbar includes a first extension portion that extends in a length direction of the heat-dissipating body and is electrically coupled to a plurality of the IGBTs that are spaced apart from one another in the length direction of the heat-dissipating body; and a second extension portion that is continuous with the first extension portion and extends in the length direction and a height direction of the heat-dissipating body and is electrically coupled to the capacitor terminal.

In this case, a sub-module may be provided in which a surface area of one surface of the capacitor body that faces the IGBT is greater than a surface area of one surface of the IGBT that faces the capacitor body.

In addition, a sub-module may be provided in which the capacitor member, the busbar member, the IGBT, and the heat-dissipating member are sequentially stacked along a height direction.

In this case, a sub-module may be provided in which the sub-module further includes a housing member that is disposed to face the IGBT with the heat-dissipating member interposed therebetween and is coupled to and supported by the heat-dissipating member; a board member that is accommodated in a housing space formed inside the housing member and is electrically connectable to the outside; and a cover member that covers the board member and is coupled to the housing member.

In addition, a sub-module may be provided in which the housing member includes a housing surface that surrounds the housing space in an outer circumferential direction; and a housing opening that is formed through the housing surface to allow communication between the housing space and the outside, and the board member includes an input module that is electrically connectable to the outside; a board body coupled to the input module and supporting the input module; a partition member extending along an outer circumference of the board body; and a board communication hole formed through the partition member to communicate with the housing opening.

In this case, a sub-module may be provided in which the cover member includes a cover body that covers the board member; and a cover communication hole formed through the cover body to allow communication between the housing space and the outside.

According to the above configuration, the sub-module according to an embodiment of the present disclosure can improve explosion-proof performance.

The sub-module is provided with an IGBT that is electrically connectable to an external power source or load. The IGBT is positioned adjacent to a heat-dissipating member for cooling generated heat. The IGBT is formed in a plate shape, and one surface of the IGBT can be coupled to the heat-dissipating member.

A capacitor member is provided adjacent to the IGBT. The capacitor member is electrically connected to the IGBT and is configured to receive and store power delivered through the IGBT. The capacitor member is disposed to face the heat-dissipating member with the IGBT interposed therebetween. In this case, the capacitor member may be disposed to face the other surface of the IGBT.

That is, one surface of the IGBT is coupled to and supported by the heat-dissipating member, and the other surface of the IGBT is arranged to face the capacitor member. In the event of an explosion of the IGBT, debris generated thereby can be prevented from scattering by the heat-dissipating member on one side and the capacitor member on the other side.

In one embodiment, the heat-dissipating member and the capacitor member may be disposed to cover, or be adjacent to, the surface of the IGBT from which the largest amount of debris is generated in the event of an explosion.

Accordingly, even without a separate component for explosion protection, debris generated by the explosion of the IGBT can be prevented from scattering by the heat-dissipating member provided for cooling and the capacitor member provided for power storage. As a result, the explosion-proof performance of the sub-module can be improved without the need for an additional component.

In addition, according to the above configuration, the sub-module according to an embodiment of the present disclosure can be miniaturized.

In one embodiment, each component of the sub-module may be stacked in the height direction. Specifically, from the lower side toward the upper side of the sub-module, the capacitor member, the busbar member electrically connecting the capacitor member to the IGBT, the IGBT, and the heat-dissipating member that contacts and cools the IGBT are sequentially stacked.

In addition, a board member for controlling the sub-module is accommodated in a housing member, and the housing member is seated on and supported by the heat-dissipating member. A cover member is coupled to the upper side of the housing member while covering the board member.

Accordingly, the space occupied by the sub-module can be minimized. As a result, both the sub-module itself and the entire modular multilevel converter including the sub-module can be reduced in size.

In addition, according to the above configuration, the sub-module according to an embodiment of the present disclosure can be easily manufactured.

As described above, the sub-module can be configured without a separate component for securing explosion-proof performance in the event of an explosion of the IGBT. That is, the number of components of the sub-module can be reduced. Accordingly, the number of members for coupling the respective components of the sub-module and the number of portions where the members are coupled can also be reduced.

As a result, the manufacturing or assembly of the sub-module can be easily performed.

Furthermore, according to the above configuration, the sub-module according to an embodiment of the present disclosure can reduce manufacturing costs.

As described above, the manufacturing or assembly of the sub-module can be easily performed. Accordingly, the time or cost required for manufacturing the sub-module can also be reduced, thereby improving economic efficiency.

Advantageous effects of the present disclosure are not limited to the above-described effects, and should be understood to include all effects that can be inferred from the configuration of the disclosure described in the detailed description or claims of the present disclosure.

### BRIEF DESCRIPTION OF THE DRAWINGS

FIG. 1 is a perspective view illustrating a sub-module according to an exemplary embodiment of the present disclosure.

FIG. 2 is a front view illustrating the sub-module of FIG. 1.

FIG. 3 is a rear view illustrating the sub-module of FIG. 1.

FIG. 4 is a left side view illustrating the sub-module of FIG. 1.

FIG. 5 is a right side view illustrating the sub-module of FIG. 1.

FIG. 6 is an exploded perspective view illustrating components of the sub-module of FIG. 1.

FIG. 7 is a perspective view illustrating a cover member included in the sub-module of FIG. 1.

FIG. 8 is a perspective view illustrating a board member included in the sub-module of FIG. 1.

FIG. 9 is a perspective view illustrating a housing member included in the sub-module of FIG. 1.

FIG. 10 is a perspective view illustrating a heat-dissipating member included in the sub-module of FIG. 1.

FIG. 11 is a perspective view illustrating an IGBT included in the sub-module of FIG. 1.

FIGS. 12 and 13 are perspective views illustrating a busbar member included in the sub-module of FIG. 1.

FIG. 14 is a perspective view illustrating a capacitor member included in the sub-module of FIG. 1.

FIGS. 15 and 16 are an exploded perspective view (FIG. 15) and a side cross-sectional view (FIG. 16) illustrating the interior of the sub-module of FIG. 1.

FIGS. 17 and 18 are a perspective view (FIG. 17) and an exploded perspective view (FIG. 18) illustrating a sub-module according to the related art.

### DETAILED DESCRIPTION

Hereinafter, exemplary embodiments of the present disclosure will be described in detail so that those of ordinary skill in the art can readily implement the present disclosure with reference to the accompanying drawings. The present disclosure may be embodied in many different forms and is not limited to the embodiments set forth herein. In the drawings, parts unrelated to the description are omitted for clarity of description of the present disclosure, and throughout the specification, same or similar reference numerals denote same elements.

The words and terms used in the present specification and claims should not be interpreted as being limited to their ordinary or dictionary meanings, but should be construed as having meanings and concepts consistent with the technical spirit of the present disclosure, in accordance with the principle that an inventor may define terms and concepts to best describe their disclosure.

Accordingly, the embodiments described in the present specification and the configurations shown in the drawings correspond to preferred embodiments of the present disclosure, and do not represent all the technical spirit of the present disclosure, so the configurations may have various examples of equivalent and modification that can replace them at the time of filing the present disclosure.

In the following description, in order to clarify the features of the present disclosure, descriptions of some components may be omitted.

### 1. Term Definition

The term “communication” used in the following description refers to a state in which one or more members are connected so as to allow fluid flow between them. In an embodiment, the communication may be established by members such as conduits, pipes, or tubes. In the following description, the term “communication” may be used to mean that one or more members are “fluidly connected” to each other.

The term “electrical connection” used in the following description refers to a state in which one or more members are connected so as to allow the transmission of electric current or electrical signals between them, and may be variously referred to as “electrical connection,” “energization,” “energizable connection,” “electrically connected state,” “enabled current flow,” “current-conducting state,” or “electrical conduction.” In an embodiment, the electrical connection may be established in a wired form using a wire member or the like, or in a wireless form using Bluetooth, Wi-Fi, RFID, or the like. In an embodiment, the electrical connection may include the meaning of “electrical communication.”

The term “fluid” used in the following description refers to any form of material that flows by external force and whose shape or volume can be changed. In an embodiment, the fluid may be a liquid such as water or a gas such as air.

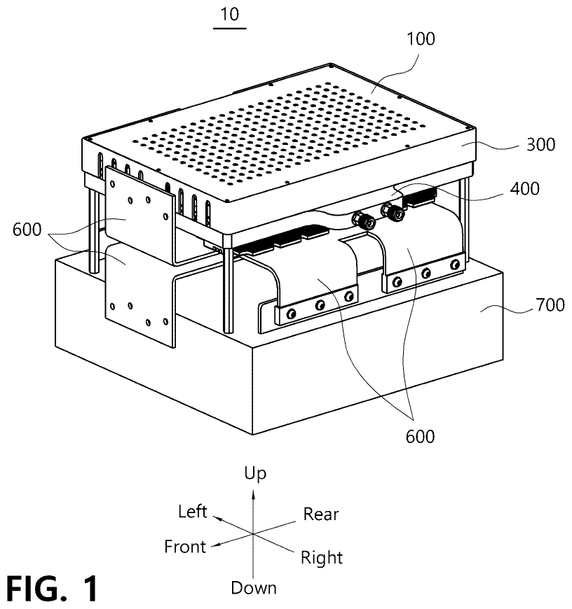

The terms “above or upper side”, “below or lower side”, “left side”, “right side”, “front side”, and “rear side” used in the following description will be understood with reference to the coordinate system shown in FIG. 1.

### 2. Description of Configuration of Sub-Module 10 According to an Embodiment of the Present Disclosure

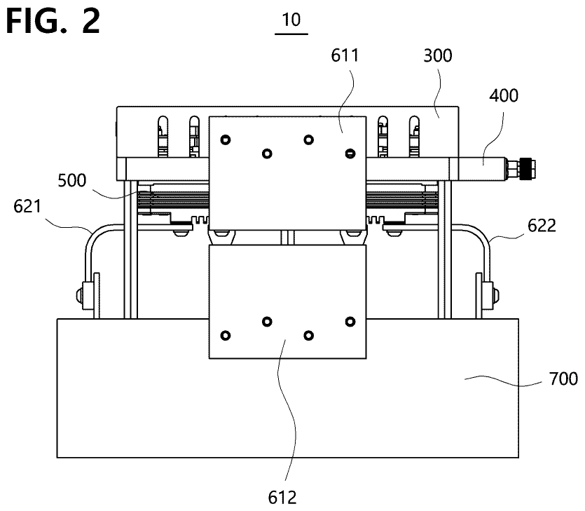

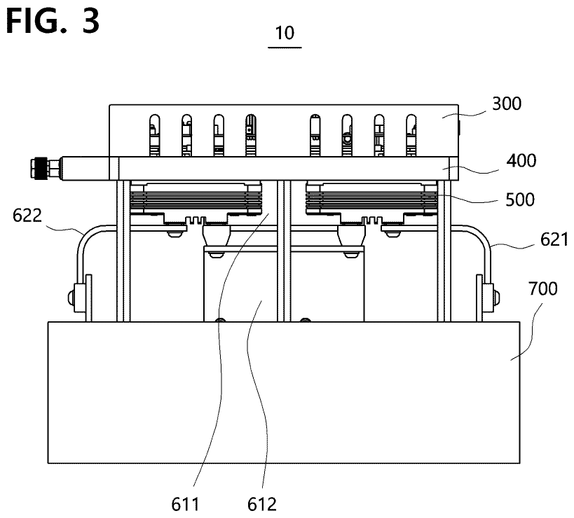

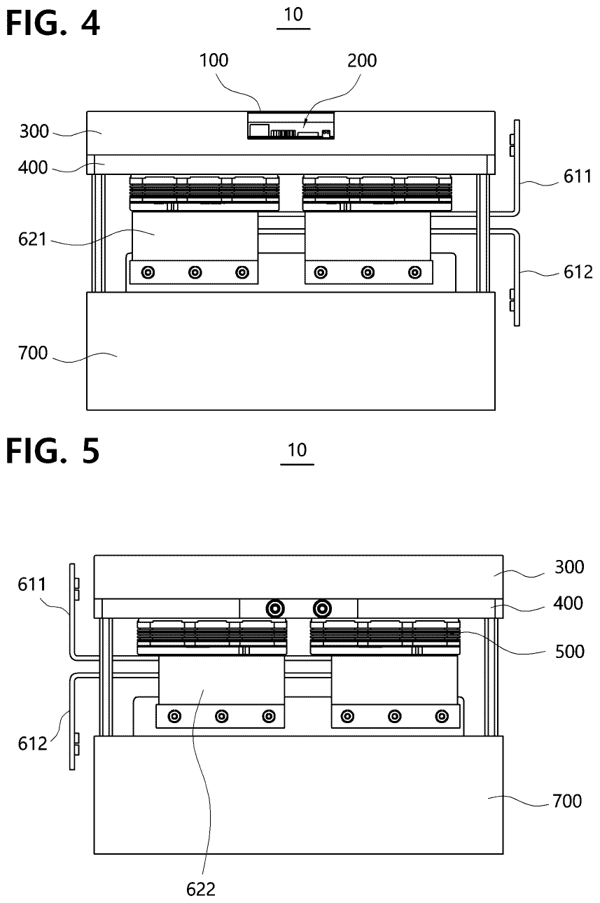

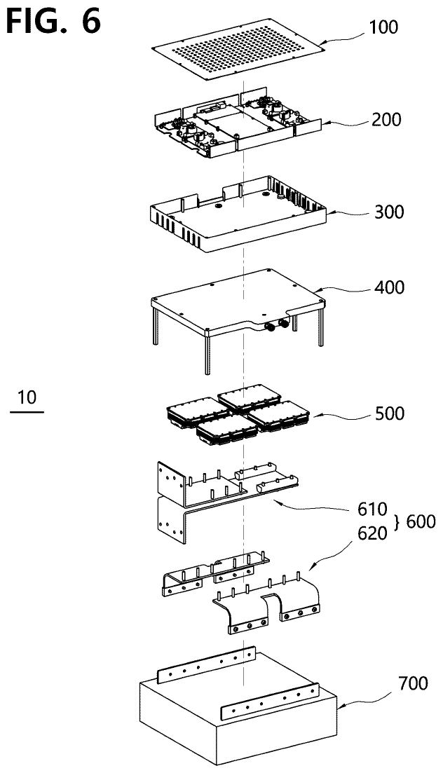

Referring to FIGS. 1 to 14, a sub-module 10 according to an embodiment of the present disclosure is illustrated.

The sub-module 10 may be provided in a modular multilevel converter and utilized therein. In one embodiment, the modular multilevel converter may function as a static synchronous compensator (STATCOM).

That is, in the above embodiment, the modular multilevel converter may function as a type of static reactive power compensator that supplements voltage loss during power transmission or distribution and improves stability.

The modular multilevel converter may include a plurality of sub-modules 10. The plurality of sub-modules 10 may be electrically connected to each other. In addition, the plurality of sub-modules 10 may each be electrically connected to an external power source or load. Power delivered from the external power source may be stored in the sub-module 10 after undergoing a voltage conversion process.

FIGS. 1 to 14 illustrate a single sub-module 10. It will be understood that, in actual implementation, a plurality of sub-modules 10 may be electrically connected to each other to constitute a modular multilevel converter. Accordingly, the capacity of the modular multilevel converter can be varied.

In the embodiment illustrated in FIGS. 1 to 14, the sub-module 10 includes a cover member 100, a board member 200, a housing member 300, a heat-dissipating member 400, an IGBT 500, a busbar member 600, and a capacitor member 700.

The cover member 100 forms a part of the outer shape of the sub-module 10. The cover member 100 covers the board member 200 accommodated in the housing member 300 and is coupled to the housing member 300. The board member 200 accommodated in the housing member 300 is prevented from being exposed to the outside by the cover member 100.

The cover member 100 forms one side in the height direction of the sub-module 10. In the illustrated embodiment, the cover member 100 forms an upper side in the height direction of the sub-module 10. That is, the cover member 100 is positioned at the uppermost portion among the components of the sub-module 10.

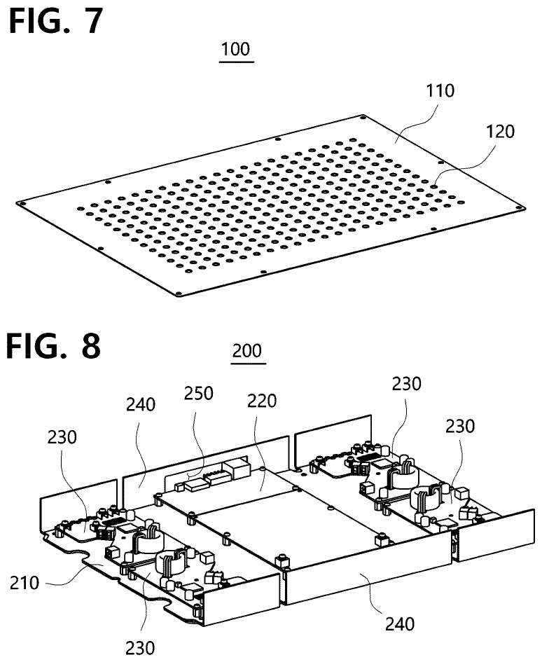

In the embodiment illustrated in FIG. 7, the cover member 100 includes a cover body 110 and a cover communication hole 120.

The cover body 110 forms the outer shape of the cover member 100. The cover body 110 may be formed to correspond to the shape of the board member 200 or the housing member 300, and may be coupled to the housing member 300 while covering the board member 200. In the illustrated embodiment, the cover body 110 is formed in a plate shape having a length in the left-right direction greater than that in the front-rear direction and a thickness in the vertical direction.

In this case, the cover body 110 may be formed such that its outer periphery is positioned inward of the inner periphery of the housing member 300. Accordingly, the cover body 110 may cover a space formed inside the housing member 300 (i.e., a housing space 320, which will be described later), be accommodated in the housing member 300, and be supported by the inner periphery of the housing member 300.

A cover communication hole 120 is formed inside the cover body 110.

The cover communication hole 120 is formed to penetrate through the cover body 110 in the thickness direction, which is the vertical direction in the illustrated embodiment. The cover communication hole 120 communicates the housing space 320 with the outside, that is, with the upper side in the illustrated embodiment. Heat generated from the board member 200 accommodated in the housing member 300 may be discharged to the outside of the housing member 300 through the cover communication hole 120.

The cover communication hole 120 may have any shape that allows the housing space 320 to communicate with the outside. In the illustrated embodiment, the cover communication hole 120 is formed as a disc-shaped space having a circular cross-section and a thickness in the vertical direction.

A plurality of cover communication holes 120 may be formed. The plurality of cover communication holes 120 are spaced apart from each other and may each allow communication between the housing space 320 and the outside. In the illustrated embodiment, the plurality of cover communication holes 120 are spaced apart from each other in the width direction (i.e., the left-right direction) and the length direction (i.e., the front-rear direction) of the cover body 110.

The board member 200 is a component that receives control signals for the operation of the sub-module 10. The board member 200 is electrically connected to an external control unit (not shown).

The board member 200 is coupled to the cover member 100. Specifically, the board member 200 is indirectly coupled to the cover member 100 by the housing member 300. One side of the board member 200 in the height direction, which is the upper side in the illustrated embodiment, is arranged to be covered by the cover member 100.

The board member 200 is coupled to the housing member 300. The board member 200 is accommodated in a housing space 320 formed inside the housing member 300 and is supported by the bottom surface and inner periphery of the housing member 300.

The board member 200 is electrically connected to the IGBT 500. Control signals or power required for the operation of the IGBT 500 may be delivered from the board member 200.

The board member 200 is electrically connected to the capacitor member 700. Control signals or power required for the operation of the capacitor member 700 may be delivered from the board member 200.

The board member 200 may be provided in any form capable of inputting, processing, and outputting information, and capable of being electrically connected to an external control unit (not shown) to receive control signals and power. In addition, the board member 200 may be provided in any form capable of delivering control signals and power to the IGBT 500 or the capacitor member 700. In one embodiment, the board member 200 may be provided as a printed circuit board (PCB) or a printed board assembly (PBA).

In the embodiment illustrated in FIG. 8, the board member 200 includes a board body 210, an input module 220, an output module 230, a partition member 240, and a board communication hole 250.

The board body 210 forms the outer shape of the board member 200. The board body 210 is accommodated in the housing member 300. One side of the board body 210 in the height direction, which is the upper side in the illustrated embodiment, may be covered by the cover member 100. The other side of the board body 210 in the height direction, which is the lower side in the illustrated embodiment, is supported by the housing body 310.

The board body 210 may be formed in a shape corresponding to the shape of the cover member 100 or the housing member 300. In the illustrated embodiment, the board body 210 is provided in a plate shape having a width in the left-right direction, a length in the front-rear direction, and a height in the vertical direction. In this case, the length of the board body 210 in the width direction is shorter than its length in the front-rear direction.

The board body 210 is coupled to the input module 220 and the output module 230. In addition, the board body 210 is continuous with the partition member 240.

The input module 220 is a component through which the board member 200 is electrically connected to an external control unit. The input module 220 is coupled to and supported by the board body 210.

The input module 220 may be provided in any form that can be electrically connected to an external control unit. In the illustrated embodiment, the input module 220 includes a port to which a connector can be coupled.

The input module 220 is positioned adjacent to the partition member 240. Specifically, the input module 220 is positioned adjacent to the board communication hole 250, which penetrates the partition member 240. Among the components of the input module 220, the port may be exposed to the outside of the housing member 300 through the board communication hole 250.

The input module 220 is electrically connected to the output module 230.

The output module 230 is a component through which the board member 200 is electrically connected to the IGBT 500 and the capacitor member 700. The output module 230 is coupled to and supported by the board body 210.

The output module 230 is electrically connected to the input module 220. The output module 230 may receive control signals from the input module 220 and may deliver them to the IGBT 500 or the capacitor member 700.

A plurality of output modules 230 may be provided. The plurality of output modules 230 may be disposed at different positions on the board body 210 and may each be electrically connected to the input module 220. In addition, one or more of the plurality of output modules 230 may be electrically connected to the IGBT 500, and another may be electrically connected to the capacitor member 700.

In the illustrated embodiment, four output modules 230 are provided and are positioned adjacent to respective corners of the board body 210. In this case, the plurality of output modules 230 may be arranged to face each other with the input module 220 interposed therebetween.

In the illustrated embodiment, a pair of output modules 230 is positioned on the front side of the board body 210, and another pair of output modules 230 is positioned on the rear side of the board body 210 to face the front-side pair with the input module 220 interposed therebetween.

The partition member 240 is continuous with the board body 210 and is configured to support the board body 210 accommodated in the housing member 300. The partition member 240 may be in contact with the inner periphery of the housing body 310. The partition member 240 extends along the outer periphery of the board body 210.

The partition member 240 may be continuous with the board body 210 at a predetermined angle. In the illustrated embodiment, the partition member 240 may extend upward perpendicularly from the board body 210.

A plurality of partition members 240 may be provided. The plurality of partition members 240 may be disposed to face each other with the interior of the board body 210 interposed therebetween. In the illustrated embodiment, the plurality of partition members 240 are continuous with respective edges in the width direction of the board body 210, that is, the left and right edges. The partition members 240 extend in the length direction of the board body 210, which is the front-rear direction in the illustrated embodiment.

Among the plurality of partition members 240, one partition member 240 positioned adjacent to the port of the input module 220—specifically, the partition member 240 located on the left side in the illustrated embodiment—is formed with a board communication hole 250.

The board communication hole 250 forms a passage through which the port provided in the input module 220 is exposed to the outside. The board communication hole 250 is formed to penetrate through the interior of the partition member 240. The board communication hole 250 is formed to penetrate the partition member 240 in the thickness direction, which is the left-right direction in the illustrated embodiment.

The board communication hole 250 may have a shape corresponding to the shape of the port provided in the input module 220. In the illustrated embodiment, the board communication hole 250 is formed as a polygonal plate-shaped space having an extension length in the front-rear direction greater than its height in the vertical direction and a thickness in the left-right direction.

The housing member 300 accommodates the board member 200. The housing member 300 is coupled to the cover member 100, such that the accommodated board member 200 is not exposed to the outside.

The housing member 300 is coupled to the cover member 100. The housing member 300 accommodates the cover member 100 and supports the cover member 100 from the radially outer side.

The housing member 300 is coupled to the heat-dissipating member 400. The housing member 300 is supported by the heat-dissipating member 400 and does not come into direct contact with the IGBT 500. In the illustrated embodiment, the housing member 300 is disposed to face the IGBT 500 with the heat-dissipating member 400 interposed therebetween.

The housing member 300 may be formed of an electrically insulating material. This is to prevent unintended electrical conduction between the board member 200 accommodated in the housing member 300 and the outside. In one embodiment, the housing member 300 may be formed of a synthetic resin material.

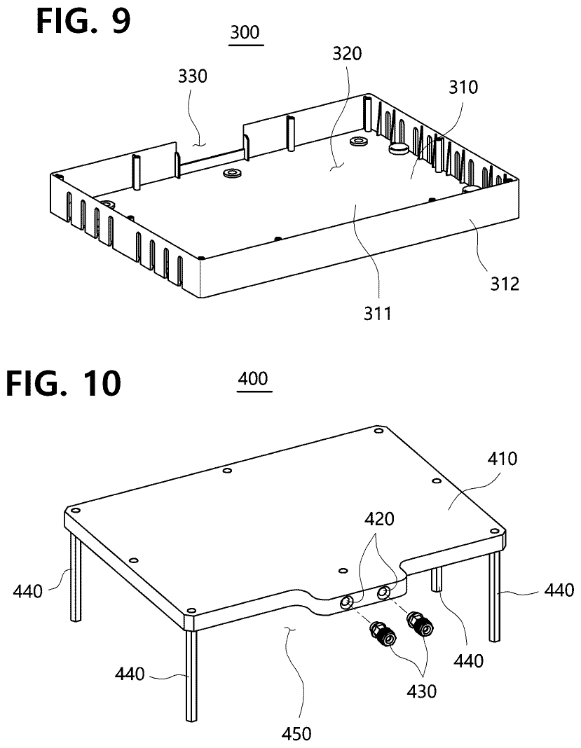

In the embodiment illustrated in FIG. 9, the housing member 300 includes a housing body 310, a housing space 320, and a housing opening 330.

The housing body 310 forms the outer shape of the housing member 300. The housing body 310 is the portion of the housing member 300 that is exposed to the outside. Among the surfaces of the housing body 310, one surface facing the heat-dissipating member 400—specifically, the lower surface in the illustrated embodiment—is coupled to and supported by the heat-dissipating member 400.

The housing body 310 is coupled to the cover member 100. The housing body 310 supports the cover member 100 from the outside. Specifically, the housing body 310 may support the outer periphery of the cover member 100 accommodated in the housing space 320.

The housing body 310 may have any shape capable of accommodating the board member 200 and being coupled to the cover member 100 and the heat-dissipating member 400. In the illustrated embodiment, the housing body 310 has a rectangular pillar shape with a length in the width direction (i.e., the left-right direction) shorter than that in the length direction (i.e., the front-rear direction), and a height in the vertical direction.

In this case, one side of the housing body 310 in the height direction—specifically, the upper side in the illustrated embodiment—is open. The board member 200 may be accommodated in the housing space 320 through the open side. As described above, the open side may be covered by the cover member 100.

In the embodiment illustrated in FIG. 9, the housing body 310 includes a first housing surface 311 and a second housing surface 312.

The first housing surface 311 is defined as one of the inner surfaces of the housing body 310. The first housing surface 311 surrounds one side of the housing space 320 in the height direction—specifically, the lower side in the illustrated embodiment. The first housing surface 311 supports the board member 200, which is accommodated in the housing space 320, from below.

The first housing surface 311 may have a shape corresponding to the shape of the board body 210. In the illustrated embodiment, the first housing surface 311 is provided in a rectangular plate shape having a length in the left-right direction shorter than that in the front-rear direction.

The first housing surface 311 is continuous with the second housing surface 312.

The second housing surface 312 is defined as another inner surface of the housing body 310. The second housing surface 312 surrounds the housing space 320 in the outer peripheral direction—specifically, from the front, rear, left, and right sides in the illustrated embodiment. The second housing surface 312 extends along the outer periphery of the first housing surface 311.

The second housing surface 312 is formed to have a predetermined height. In one embodiment, the second housing surface 312 may be formed to have a height equal to or greater than that of the board member 200. Therefore, the board member 200 accommodated in the housing space 320 is not exposed to the outside of the housing body 310.

Although reference numerals are not assigned, a plurality of ribs extending in the height direction, that is, the vertical direction, may be formed on the second housing surface 312. The plurality of ribs may support the outer periphery of the board body 210 accommodated in the housing space 320.

A housing opening 330 is formed at a position on the second housing surface 312 corresponding to the board communication hole 250. The board communication hole 250 and the housing opening 330 communicate with each other, thereby forming a passage through which the housing space 320 communicates with the outside.

The housing space 320 is a space formed inside the housing body 310. The housing space 320 accommodates the board member 200. To this end, the housing space 320 may be formed in a shape corresponding to the board member 200. In the illustrated embodiment, the housing space 320 is formed as a rectangular pillar-shaped space having a length in the left-right direction shorter than that in the front-rear direction and a height in the vertical direction.

One side of the housing space 320 in the height direction—specifically, the upper side in the illustrated embodiment—is open. The board member 200 may be accommodated in the housing space 320 through the open side. In addition, the open side of the housing space 320 may be covered by the cover member 100.

The housing space 320 communicates with the outside. Specifically, the housing space 320 communicates with the outside through the cover communication hole 120. Heat generated from the board member 200 may be discharged through the cover communication hole 120 or may be cooled by external air introduced through the cover communication hole 120.

In addition, the housing space 320 communicates with the outside through the housing opening 330. The input module 220 of the board member 200 may be electrically connected to an external connector through the housing opening 330 and the board communication hole 250 that communicates therewith.

The housing opening 330 is a component that allows the housing space 320 to communicate with the outside. The housing opening 330 communicates with the board communication hole 250 and forms a passage for connecting a connector to the input module 220 accommodated in the housing space 320.

The housing opening 330 is formed to penetrate the second housing surface 312. Specifically, the housing opening 330 is formed to penetrate one side of the second housing surface 312 where the port of the input module 220 is located—specifically, the left side in the illustrated embodiment.

The housing opening 330 communicates with the board communication hole 250. The housing opening 330 may be arranged to overlap with the board communication hole 250 in the width direction of the housing body 310, which is the left-right direction in the illustrated embodiment.

The housing opening 330, which communicates with the board communication hole 250, may have any shape capable of forming a passage through which a connector passes. In the illustrated embodiment, the housing opening 330 is formed as a rectangular plate-shaped space having an extension length in the front-rear direction greater than its height in the vertical direction and a thickness in the left-right direction.

The heat-dissipating member 400 is configured to exchange heat with the IGBT 500 and cool the IGBT 500. In one embodiment, the heat-dissipating member 400 is in contact with the IGBT 500 and may exchange heat with the IGBT 500 in the form of conduction.

The heat-dissipating member 400 supports the housing member 300 and the board member 200 accommodated therein. In one embodiment, the heat-dissipating member 400 may support the housing member 300 from below. Accordingly, the heat-dissipating member 400 is positioned above the IGBT 500 and below the housing member 300.

The heat-dissipating member 400 is coupled to the capacitor member 700. In this case, the heat-dissipating member 400 may form a predetermined space and be coupled to the capacitor member 700. The space formed between the heat-dissipating body 410 of the heat-dissipating member 400 and the capacitor body 710 of the capacitor member 700 accommodates the IGBT 500 and the busbar member 600.

In the embodiment illustrated in FIG. 10, the heat-dissipating member 400 includes a heat-dissipating body 410, a heat-dissipating communication part 420, a heat-dissipating cap 430, a heat-dissipating support part 440, and an IGBT-accommodating part 450.

The heat-dissipating body 410 forms a part of the outer shape of the heat-dissipating member 400. The heat-dissipating body 410 is configured to come into direct contact with the IGBT 500 and exchange heat with the IGBT 500.

The heat-dissipating body 410 may be provided in any form capable of receiving heat generated from the IGBT 500 and discharging it to the outside. In the illustrated embodiment, the heat-dissipating body 410 is configured to cool the IGBT 500 using a coolant such as water. That is, in the above embodiment, the heat-dissipating body 410 is provided as a water-cooled type. In the above embodiment, a flow path (not shown) through which the introduced coolant flows may be formed inside the heat-dissipating body 410.

The heat-dissipating body 410 may be formed in a shape corresponding to the shape of the housing body 310 and the arrangement of the plurality of IGBTs 500. In the illustrated embodiment, the heat-dissipating body 410 is provided in a polygonal plate shape having an extension length in the front-rear direction greater than that in the left-right direction and a thickness in the vertical direction.

In this case, the heat-dissipating body 410 may be formed to have a larger surface area than the total surface area of the plurality of IGBTs 500. Specifically, one surface of the heat-dissipating body 410 facing the IGBTs 500—namely, the lower surface in the illustrated embodiment—may be arranged to overlap with the entire plurality of IGBTs 500 in the height direction, that is, the vertical direction. Accordingly, scattering debris generated when the plurality of IGBTs 500 explode may be blocked from dispersing to the outside by the heat-dissipating body 410.

The heat-dissipating body 410 may be formed of a thermally conductive material. This is to enable smooth heat exchange with the IGBT 500 and effectively cool the IGBT 500. In one embodiment, the heat-dissipating body 410 may be formed to include a metal material such as aluminum (Al).

The heat-dissipating body 410 supports the housing member 300 from below. As described above, since the housing member 300 is formed of an electrically insulating material, unintended electrical conduction between the IGBT 500 and the board member 200 can be prevented even if the housing member 300 comes into contact with the heat-dissipating body 410.

The heat-dissipating body 410 is coupled to the IGBT 500. In the illustrated embodiment, the lower surface of the heat-dissipating body 410 is in direct contact with the upper surface of the IGBT 500.

As the heat-dissipating body 410 comes into direct contact with the IGBT 500, the heat-dissipating body 410 may be configured to shield one side of the IGBT 500 in the height direction—specifically, the upper side in the illustrated embodiment. Accordingly, in the event of an explosion of the IGBT 500, the heat-dissipating body 410 can prevent the scattering debris from dispersing upward.

That is, the heat-dissipating body 410 may serve both to cool the IGBT 500 and to provide an explosion-proof function for the IGBT 500.

The heat-dissipating body 410 is positioned to be spaced apart from the capacitor body 710. Accordingly, a predetermined space is formed between the heat-dissipating body 410 and the capacitor body 710. The IGBT 500 and the busbar member 600 may be accommodated in the space. This spacing is achieved by the heat-dissipating support part 440, which is coupled to both the heat-dissipating body 410 and the capacitor body 710.

The heat-dissipating communication part 420 allows communication between a flow path (not shown) formed inside the heat-dissipating body 410 and the outside. A coolant for cooling the IGBT 500 may be introduced into the flow path (not shown) through the heat-dissipating communication part 420. The introduced coolant may flow through the flow path (not shown), exchange heat with the IGBT 500, and then be discharged to the outside of the heat-dissipating body 410 through the heat-dissipating communication part 420.

The heat-dissipating communication part 420 may be formed at any position that allows communication between the flow path (not shown) and the outside. In the illustrated embodiment, the heat-dissipating communication part 420 is formed to penetrate through one edge in the width direction of the heat-dissipating body 410, specifically, the right edge in the illustrated embodiment.

A plurality of heat-dissipating communication parts 420 may be provided. One of the plurality of heat-dissipating communication parts 420 may function as a passage through which coolant is introduced. Another one of the plurality of heat-dissipating communication parts 420 may function as a passage through which coolant flows out. In the illustrated embodiment, a pair of heat-dissipating communication parts 420 is provided and arranged spaced apart from each other in the length direction, that is, the front-rear direction of the heat-dissipating body 410.

The heat-dissipating communication part 420 may be sealed by the heat-dissipating cap 430.

The heat-dissipating cap 430 opens or closes the heat-dissipating communication part 420. The heat-dissipating cap 430 is detachably coupled to the heat-dissipating communication part 420.

The heat-dissipating cap 430 may have any shape capable of opening or closing the heat-dissipating communication part 420. In the illustrated embodiment, the heat-dissipating cap 430 has a cylindrical shape with a circular cross-section and a length in the left-right direction, corresponding to the shape of the heat-dissipating communication part 420.

A sealing member (reference numeral not assigned), formed of rubber, silicone, or the like, may be provided on the outer periphery of the heat-dissipating cap 430. The sealing member may be configured to seal the heat-dissipating communication part 420.

A plurality of heat-dissipating caps 430 may be provided. The plurality of heat-dissipating caps 430 are detachably coupled to the respective heat-dissipating communication parts 420, and may open or close the heat-dissipating communication parts 420. In the illustrated embodiment, a pair of heat-dissipating caps 430 is provided and detachably coupled to a pair of heat-dissipating communication parts 420, respectively.

The heat-dissipating support part 440 supports the heat-dissipating body 410. The heat-dissipating body 410 may be coupled to the capacitor member 700 by the heat-dissipating support part 440 in a manner spaced apart from the capacitor body 710.

The heat-dissipating support part 440 extends in the thickness direction of the heat-dissipating body 410, which is the vertical direction in the illustrated embodiment. One end of the heat-dissipating support part 440 in the extension direction—specifically, the upper end in the illustrated embodiment—is coupled to the heat-dissipating body 410. In the illustrated embodiment, the one end of the heat-dissipating support part 440 is inserted into and coupled to an opening formed through the thickness direction, that is, the vertical direction, at a corner of the heat-dissipating body 410.

The other end of the heat-dissipating support part 440 in the extension direction—specifically, the lower end in the illustrated embodiment—is coupled to the capacitor body 710. In one embodiment, the other end of the heat-dissipating support part 440 may be inserted into and coupled to an opening (not shown) formed in the capacitor body 710.

A plurality of heat-dissipating support parts 440 may be provided. The plurality of heat-dissipating support parts 440 may be coupled to the heat-dissipating body 410 at different positions to support it. In the illustrated embodiment, four heat-dissipating support parts 440 are provided and are respectively coupled to the front left and right corners and the rear left and right corners of the heat-dissipating body 410.

The heat-dissipating support part 440 may extend by a length equal to or greater than the combined thickness of the IGBT 500 and the busbar member 600. Accordingly, an IGBT-accommodating part 450 may be formed between the heat-dissipating body 410 and the capacitor body 710, which are spaced apart by the heat-dissipating support part 440.

The IGBT-accommodating part 450 is a space formed between the heat-dissipating body 410 and the capacitor body 710. The IGBT-accommodating part 450 accommodates the IGBT 500 and the busbar member 600.

As described above, in the sub-module 10 according to an embodiment of the present disclosure, the heat-dissipating body 410 may be configured to perform an explosion-proof function for the IGBT 500. In this case, the heat-dissipating body 410 may perform the explosion-proof function for the upper side of the IGBT 500. The explosion-proof function for the lower side of the IGBT 500 may be performed by the capacitor body 710.

That is, the upper side of the IGBT 500 accommodated in the IGBT-accommodating part 450 is surrounded by the heat-dissipating body 410, and the lower side is surrounded by the capacitor body 710. Accordingly, even in the event of an explosion of the IGBT 500, scattering debris is blocked by the heat-dissipating body 410 and the capacitor body 710 and thus prevented from dispersing.

The IGBT-accommodating part 450 may have a shape corresponding to the shape of the heat-dissipating body 410 or the capacitor body 710. In the illustrated embodiment, the IGBT-accommodating part 450 is formed as a polygonal pillar-shaped space having a width in the left-right direction shorter than its length in the front-rear direction and a height in the vertical direction.

The IGBT-accommodating part 450 may be formed to have a height corresponding to the extension length of the heat-dissipating support part 440. As described above, the heat-dissipating support part 440 may extend by a length equal to or greater than the combined height of the IGBT 500 and the busbar member 600. Accordingly, the IGBT-accommodating part 450 may also be formed to have a height equal to or greater than the combined height of the IGBT 500 and the busbar member 600.

The IGBT 500 controls current flowing into or out of the sub-module 10. In one embodiment, the IGBT 500 may function as a switching device.

The IGBT 500 is accommodated in the IGBT-accommodating part 450. The IGBT 500 accommodated in the IGBT-accommodating part 450 is coupled to the heat-dissipating body 410 and the capacitor body 710. In the illustrated embodiment, the upper side of the IGBT 500 is in contact with and supported by the lower side of the heat-dissipating body 410. In addition, the lower side of the IGBT 500 is in contact with and supported by the upper side of the capacitor body 710.

The IGBT 500 may be in surface contact with the heat-dissipating body 410.

Specifically, the respective surfaces of the IGBT 500 and the heat-dissipating body 410 facing each other may be in contact. Accordingly, heat generated from the IGBT 500 may be transferred to the coolant flowing inside the heat-dissipating body 410, thereby cooling the IGBT 500.

The IGBT 500 is electrically connected to the board member 200. The IGBT 500 may be operated by a control signal applied from the board member 200.

The IGBT 500 is electrically connected to the busbar member 600. The IGBT 500 may receive power from an external power source through the busbar member 600.

The IGBT 500 is electrically connected to the capacitor member 700. Power delivered to the IGBT 500 may be adjusted in voltage by the IGBT 500 and then delivered to the capacitor member 700 for storage.

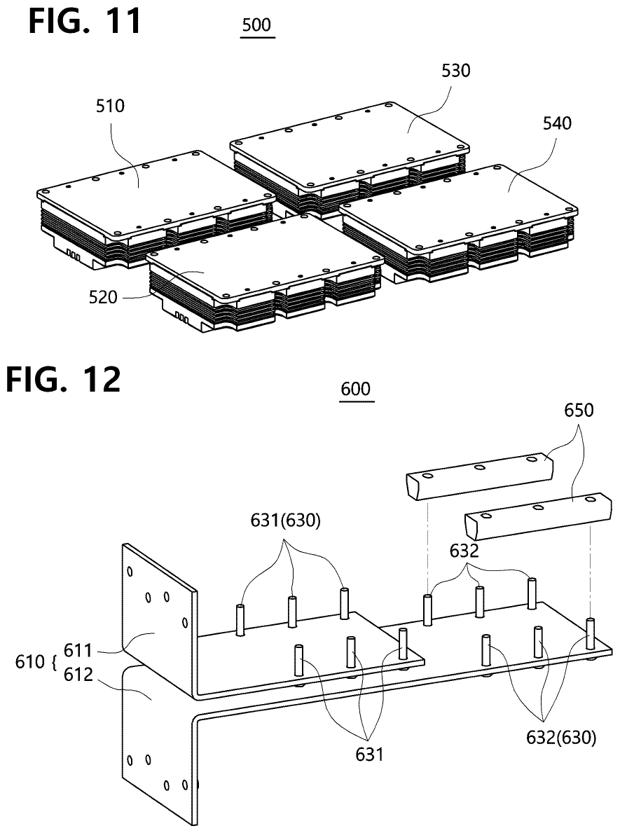

A plurality of IGBTs 500 may be provided. The plurality of IGBTs 500 may be electrically connected to the board member 200, the busbar member 600, and the capacitor member 700, respectively. In the illustrated embodiment shown in FIG. 11, four IGBTs 500 are provided, including a first IGBT 510, a second IGBT 520, a third IGBT 530, and a fourth IGBT 540.

The first and second IGBTs 510 and 520 are positioned closer to one side in the length direction of the heat-dissipating body 410—specifically, the front side in the illustrated embodiment. The third and fourth IGBTs 530 and 540 are positioned closer to the other side in the length direction of the heat-dissipating body 410—specifically, the rear side in the illustrated embodiment.

In this case, the first to fourth IGBTs 510, 520, 530, and 540 are spaced apart from one another. Accordingly, direct electrical conduction between the first to fourth IGBTs 510, 520, 530, and 540 can be prevented.

The busbar member 600 electrically connects the sub-module 10 to an external power source or load. In addition, the busbar member 600 electrically connects various components of the sub-module 10, such as the IGBT 500 and the capacitor member 700.

The busbar member 600 is coupled to the IGBT 500. The busbar member 600 may be arranged to at least partially surround the IGBT 500. In the illustrated embodiment, the busbar member 600 is arranged to partially surround the lower side of the IGBT 500.

The busbar member 600 is coupled to the capacitor member 700. The busbar member 600 may be arranged to at least partially surround the capacitor member 700. In the illustrated embodiment, the busbar member 600 is arranged to partially surround the upper side of the capacitor body 710.

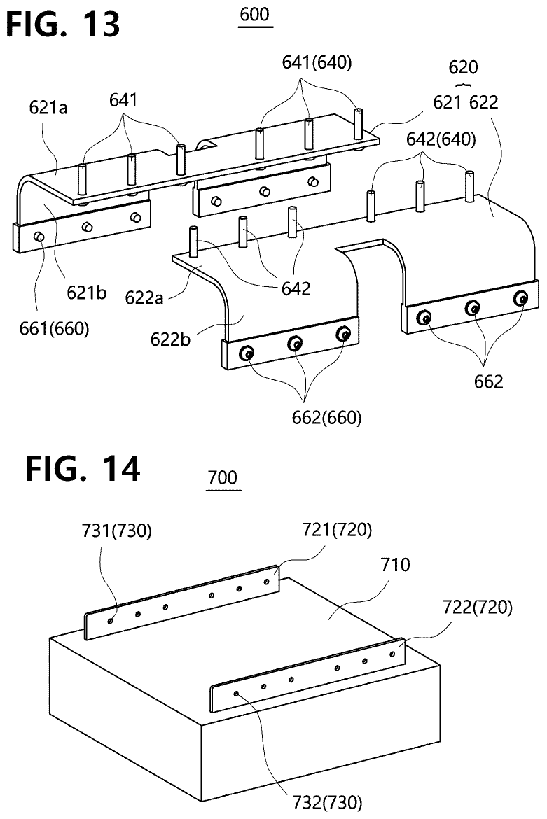

In the embodiments illustrated in FIGS. 12 and 13, the busbar member 600 includes an input busbar 610, an output busbar 620, an input fastening member 630, an output fastening member 640, a support member 650, and a capacitor fastening member 660.

The input busbar 610 electrically connects an external power source or load to the IGBT 500. The input busbar 610 is electrically coupled to the external power source or load and to the IGBT 500.

The input busbar 610 may have any shape capable of electrically connecting an external power source or load to the IGBT 500. In the illustrated embodiment, the input busbar 610 includes a first portion that extends in the vertical direction and is located on the front side, and a second portion that extends in the front-rear direction and is located on the rear side.

The first portion is electrically connected to an external power source or load. The second portion is electrically connected to the IGBT 500.

As described above, a plurality of IGBTs 500 may be provided, including the first to fourth IGBTs 510, 520, 530, and 540. Accordingly, a plurality of input busbars 610 may also be provided to electrically connect one or more of the plurality of IGBTs 500 to an external power source or load.

In the embodiment illustrated in FIG. 12, the input busbar 610 includes a first input busbar 611 and a second input busbar 612.

The first input busbar 611 electrically connects the first and second IGBTs 510 and 520, which are positioned closer to the front side among the plurality of IGBTs 500, to an external power source or load. The first input busbar 611 is electrically coupled to the first IGBT 510 and the second IGBT 520, respectively.

The first input busbar 611 is coupled to a first input fastening member 631. The first input fastening member 631 may pass through the first input busbar 611 and may be coupled to the first and second IGBTs 510 and 520, respectively.

The portion of the first input busbar 611 that is coupled to the first and second IGBTs 510 and 520—namely, the second portion—may be formed to extend at least over the distance by which the first and second IGBTs 510 and 520 are spaced apart in the width direction. In other words, the first input busbar 611 may be formed and arranged to at least partially overlap with the first and second IGBTs 510 and 520 in the vertical direction. Accordingly, the first input busbar 611 can be electrically coupled to the first and second IGBTs 510 and 520, respectively.

A plurality of through holes (reference numerals not assigned) may be formed in the first portion of the first input busbar 611. The first input fastening member 631 may be inserted through and coupled to the through holes.

The second input busbar 612 electrically connects the third and fourth IGBTs 530 and 540, which are positioned closer to the rear side among the plurality of IGBTs 500, to an external power source or load. The second input busbar 612 is electrically coupled to the third IGBT 530 and the fourth IGBT 540, respectively.

The second input busbar 612 is coupled to a second input fastening member 632. The second input fastening member 632 passes through the second input busbar 612 and may be coupled to the third and fourth IGBTs 530 and 540, respectively.

The portion of the second input busbar 612 that is coupled to the third and fourth IGBTs 530 and 540—namely, the second portion—may be formed to extend at least over the distance by which the third and fourth IGBTs 530 and 540 are spaced apart in the width direction. In other words, the second input busbar 612 may be formed and arranged to at least partially overlap with the third and fourth IGBTs 530 and 540 in the vertical direction. Accordingly, the second input busbar 612 can be electrically coupled to the third and fourth IGBTs 530 and 540, respectively.

A plurality of through holes (reference numerals not assigned) may be formed in the second portion of the second input busbar 612. The second input fastening member 632 may be inserted through and coupled to the through holes.

In this case, the first input busbar 611 is disposed above and spaced apart from the second input busbar 612. Accordingly, a component is required to electrically connect the relatively lower-positioned second input busbar 612 to the third and fourth IGBTs 530 and 540.

To this end, the second input busbar 612 may be electrically coupled to the third and fourth IGBTs 530 and 540 through the support member 650.

The output busbar 620 electrically connects the IGBT 500 to the capacitor member 700. The output busbar 620 is electrically connected to the IGBT 500 and the capacitor member 700, respectively.

Power delivered to the IGBT 500 through the input busbar 610 may be transferred to the capacitor member 700 through the output busbar 620. In addition, power stored in the capacitor member 700 may be delivered to an external load through the output busbar 620 and the IGBT 500 in sequence, and then through the input busbar 610.

The output busbar 620 may have any shape capable of electrically connecting the IGBT 500 to the capacitor member 700. In the illustrated embodiment, the output busbar 620 includes a first portion that extends horizontally in the left-right direction, and a second portion that is continuously rounded outward from the first portion and extends vertically in the vertical direction. Both the first portion and the second portion extend in the front-rear direction.

The first portion is coupled to the IGBT 500 to conduct electricity. The second portion is coupled to a capacitor terminal 720 to conduct electricity. In this case, the output busbar 620 is arranged to be spaced apart from the input busbar 610 so as to prevent direct electrical conduction.

As described above, a plurality of IGBTs 500 may be provided, including the first to fourth IGBTs 510, 520, 530, and 540. Accordingly, a plurality of output busbars 620 may also be provided to electrically connect one or more of the plurality of IGBTs 500 to the capacitor member 700.

In the embodiment illustrated in FIG. 13, the output busbar 620 includes a first output busbar 621 and a second output busbar 622.

The first output busbar 621 electrically connects a pair of IGBTs 500, which are positioned closer to one side in the width direction among the plurality of IGBTs 500, to the capacitor member 700. In the illustrated embodiment, the first output busbar 621 electrically connects the first and third IGBTs 510 and 530, which are positioned closer to the left side, to a first capacitor terminal 721. The first output busbar 621 is electrically connected to the first and third IGBTs 510 and 530 and the first capacitor terminal 721, respectively.

The first output busbar 621 is coupled to a first output fastening member 641. The first output fastening member 641 may pass through the first output busbar 621 and may be coupled to the first and third IGBTs 510 and 530, respectively.

The first output busbar 621 may include one portion that is coupled to the first and third IGBTs 510 and 530, and another portion that is coupled to the first capacitor terminal 721. In the embodiment illustrated in FIG. 13, the first output busbar 621 includes a first extension portion 621a (i.e., the first portion) and a second extension portion 621b (i.e., the second portion).

The first extension portion 621a is the portion of the first output busbar 621 that is coupled to the first and third IGBTs 510 and 530. The first extension portion 621a may extend over a distance equal to or greater than the spacing between the first and third IGBTs 510 and 530 in the length direction.

In other words, the first extension portion 621a may extend in the front-rear direction to at least partially overlap with the first and third IGBTs 510 and 530, and may be positioned below the first and third IGBTs 510 and 530. Accordingly, the first output busbar 621 can be electrically coupled to the first and third IGBTs 510 and 530, respectively.

A plurality of through holes (reference numerals not assigned) may be formed in the first extension portion 621a. The first output fastening member 641 may be inserted through and coupled to the through holes.

The first extension portion 621a extends in the horizontal direction, and its extension length in the width direction (i.e., the left-right direction) is shorter than its extension length in the length direction (i.e., the front-rear direction).

The first extension portion 621a is continuous with the second extension portion 621b at a predetermined angle. In this case, the portion where the first extension portion 621a is continuous with the second extension portion 621b is formed in a rounded shape that bulges outward, so that unintended contact with and electrical conduction to the input busbar 610 can be prevented.

The second extension portion 621b is the portion of the first output busbar 621 that is electrically connected to the first capacitor terminal 721. The second extension portion 621b is continuous with the first extension portion 621a and is electrically coupled to the first capacitor terminal 721.

The second extension portion 621b extends in the same direction as the first extension portion 621a, which is the front-rear direction in the illustrated embodiment. In one embodiment, the second extension portion 621b may extend by the same length as the first extension portion 621a.

A plurality of through holes (reference numerals not assigned) may be formed in the second extension portion 621b. A first capacitor fastening member 661 may be inserted through and coupled to the through holes.

The second output busbar 622 electrically connects another pair of IGBTs 500, which are positioned closer to the other side in the width direction among the plurality of IGBTs 500, to the capacitor member 700. In the illustrated embodiment, the second output busbar 622 electrically connects the second and fourth IGBTs 520 and 540, which are positioned closer to the right side, to the second capacitor terminal 722. The second output busbar 622 is electrically connected to the second and fourth IGBTs 520 and 540 and the second capacitor terminal 722, respectively.

The second output busbar 622 is coupled to a second output fastening member 642. The second output fastening member 642 may pass through the second output busbar 622 and may be coupled to the second and fourth IGBTs 520 and 540, respectively.

The second output busbar 622 may include one portion that is coupled to the second and fourth IGBTs 520 and 540, and another portion that is coupled to the second capacitor terminal 722. In the embodiment illustrated in FIG. 13, the second output busbar 622 includes a first extension portion 622a (i.e., the first portion) and a second extension portion 622b (i.e., the second portion).

The first extension portion 622a is the portion of the second output busbar 622 that is coupled to the second and fourth IGBTs 520 and 540. The first extension portion 622a may extend over a distance equal to or greater than the spacing between the second and fourth IGBTs 520 and 540 in the length direction.

In other words, the first extension portion 622a may extend in the front-rear direction to at least partially overlap with the second and fourth IGBTs 520 and 540, and may be positioned below the second and fourth IGBTs 520 and 540. Accordingly, the second output busbar 622 can be electrically coupled to the second and fourth IGBTs 520 and 540, respectively.

A plurality of through holes (reference numerals not assigned) may be formed in the first extension portion 622a. The first output fastening member 641 may be inserted through and coupled to the through holes.

The first extension portion 622a extends in the horizontal direction, and its extension length in the width direction (i.e., the left-right direction) is shorter than its extension length in the length direction (i.e., the front-rear direction).

The first extension portion 622a is continuous with the second extension portion 622b at a predetermined angle. In this case, the portion where the first extension portion 622a is continuous with the second extension portion 622b is formed in a rounded shape that bulges outward, so that unintended contact with and electrical conduction to the input busbar 610 can be prevented.

The second extension portion 622b is the portion of the second output busbar 622 that is electrically connected to the second capacitor terminal 722. The second extension portion 622b is continuous with the first extension portion 622a and is electrically coupled to the second capacitor terminal 722.

The second extension portion 622b extends in the same direction as the first extension portion 622a, which is the front-rear direction in the illustrated embodiment. In one embodiment, the second extension portion 622b may extend by the same length as the first extension portion 622a.

A plurality of through holes (reference numerals not assigned) may be formed in the second extension portion 622b. A first capacitor fastening member 661 may be inserted through and coupled to the through holes.

The input fastening member 630 couples the input busbar 610 to the IGBT 500. The input fastening member 630 is inserted through a through hole formed in the input busbar 610 and may be coupled to the IGBT 500.

The input fastening member 630 may be provided in any form capable of coupling the input busbar 610 to the IGBT 500. In the illustrated embodiment, the input fastening member 630 is provided in the form of a screw member.

A plurality of input fastening members 630 may be provided. Some of the plurality of input fastening members 630 may couple the first input busbar 611 to the first and second IGBTs 510 and 520. The remaining input fastening members 630 may couple the second input busbar 612 to the third and fourth IGBTs 530 and 540.

In the illustrated embodiment, the input fastening member 630 includes a first input fastening member 631 and a second input fastening member 632. The first input fastening member 631 couples the first input busbar 611 to the first and second IGBTs 510 and 520. The second input fastening member 632 couples the second input busbar 612 to the third and fourth IGBTs 530 and 540.

The output fastening member 640 couples the output busbar 620 to the IGBT 500. The output fastening member 640 is inserted through a through hole formed in the output busbar 620 and may be coupled to the IGBT 500.

The output fastening member 640 may be provided in any form capable of coupling the output busbar 620 to the IGBT 500. In the illustrated embodiment, the output fastening member 640 is provided in the form of a screw member.

A plurality of output fastening members 640 may be provided. Some of the plurality of output fastening members 640 may couple the first output busbar 621 to the first and third IGBTs 510 and 530. The remaining output fastening members 640 may couple the second output busbar 622 to the second and fourth IGBTs 520 and 540.

In the illustrated embodiment, the output fastening member 640 includes a first output fastening member 641 and a second output fastening member 642. The first output fastening member 641 couples the first output busbar 621 to the first and third IGBTs 510 and 530. The second output fastening member 642 couples the second output busbar 622 to the second and fourth IGBTs 520 and 540.

The support member 650 electrically connects the second input busbar 612 to the IGBT 500. The support member 650 is configured to compensate for the distance to the IGBT 500 based on the position of the second input busbar 612.

As described above, the first input busbar 611 is positioned above the second input busbar 612 and is directly and electrically coupled to the first and second IGBTs 510 and 520, respectively. In this case, the second input busbar 612 is positioned below the first input busbar 611 and is arranged to be spaced apart from the third and fourth IGBTs 530 and 540.

Accordingly, the support member 650 is positioned between the third and fourth IGBTs 530 and 540 and the second input busbar 612, and is coupled to and in contact with the third and fourth IGBTs 530 and 540 and the second input busbar 612, respectively, to conduct electricity. As a result, the third and fourth IGBTs 530 and 540 and the second input busbar 612 can be electrically connected to each other.

The support member 650 may have any shape capable of electrically connecting the third and fourth IGBTs 530 and 540 to the second input busbar 612. In the embodiment illustrated in FIG. 12, the support member 650 has a rectangular pillar shape, with an extension length in the front-rear direction greater than that in the left-right direction, and a height in the vertical direction.

A through hole may be formed to penetrate through the interior of the support member 650. The through hole may be arranged to overlap with a through hole formed in the second input busbar 612. The second input fastening member 632 may pass through the through hole formed in the second input busbar 612 and then through the through hole formed in the support member 650, and may be coupled to the third and fourth IGBTs 530 and 540.

A plurality of support members 650 may be provided. The plurality of support members 650 may be disposed at different positions of the second input busbar 612 and may be electrically coupled to the third and fourth IGBTs 530 and 540, respectively.

In the illustrated embodiment, a pair of support members 650 is provided. The support member 650 positioned closer to the left side of the second input busbar 612 electrically connects the third IGBT 530 to the second input busbar 612. The support member 650 positioned closer to the right side of the second input busbar 612 electrically connects the fourth IGBT 540 to the second input busbar 612.

The capacitor fastening member 660 couples the output busbar 620 to the capacitor terminal 720. The capacitor fastening member 660 is inserted through a through hole formed in the output busbar 620 and may be coupled to the capacitor terminal 720.

The capacitor fastening member 660 may be provided in any form capable of coupling the output busbar 620 to the capacitor terminal 720. In the illustrated embodiment, the capacitor fastening member 660 is provided in the form of a screw member.

A plurality of capacitor fastening members 660 may be provided. Some of the plurality of capacitor fastening members 660 may couple the first output busbar 621 to the first capacitor terminal 721. The remaining capacitor fastening members 660 may couple the second output busbar 622 to the second capacitor terminal 722.

In the illustrated embodiment, the capacitor fastening member 660 includes a first capacitor fastening member 661 and a second capacitor fastening member 662. The first capacitor fastening member 661 couples the first output busbar 621 to the first capacitor terminal 721. The second capacitor fastening member 662 couples the second output busbar 622 to the second capacitor terminal 722.

The capacitor member 700 receives and stores power delivered from an external power source to the sub-module 10. The power stored by the capacitor member 700 may be delivered to an external load. The capacitor member 700 is electrically connected to the external power source or load through the IGBT 500 and the busbar member 600.

The capacitor member 700 is coupled to the heat-dissipating member 400. As described above, the capacitor member 700 is arranged to be spaced apart from the heat-dissipating body 410 by the heat-dissipating support part 440. The IGBT-accommodating part 450 formed between the capacitor member 700 and the heat-dissipating body 410 accommodates the IGBT 500 and the busbar member 600.

The capacitor member 700 is coupled to the IGBT 500 to conduct electricity.

Specifically, the capacitor member 700 is coupled to and electrically connected to the IGBT 500 via the output busbar 620.

The capacitor member 700 may include a capacitor element (not shown) therein. The capacitor element (not shown) may be electrically connected to the output busbar 620 and the IGBT 500 via the capacitor terminal 720, respectively.

Accordingly, the capacitor element (not shown) may store electrical energy input to the sub-module 10. The electrical energy stored in the capacitor element (not shown) may be used as a power source for operating each component of the sub-module 10. In addition, the electrical energy may be supplied as reactive power to an external power system to which the sub-module 10 is electrically connected.

In the illustrated embodiment, the capacitor member 700 forms the other side in the height direction of the sub-module 10. In the illustrated embodiment, the capacitor member 700 forms the lowermost portion of the sub-module 10.

Accordingly, it will be understood that, in the sub-module 10 according to an embodiment of the present disclosure, the cover member 100, the board member 200 and the housing member 300 accommodating the same, the heat-dissipating member 400, the IGBT 500, the busbar member 600, and the capacitor member 700 are sequentially arranged from the upper side toward the lower side.

Accordingly, the volume of the space occupied by the sub-module 10 can be reduced. As a result, the sub-module 10 can be miniaturized, and the overall size of the modular multilevel converter configured by a plurality of sub-modules 10 can also be reduced.

In addition, the capacitor member 700 is positioned below the IGBT 500 and is configured to support the IGBT 500. Specifically, the capacitor member 700 may be coupled to the IGBT 500 via the output busbar 620 and may support the IGBT 500.

As described above, the IGBT 500 may be provided in a plate shape having a surface in the horizontal direction and a thickness in the vertical direction. Accordingly, in the event of an explosion of the IGBT 500, scattering debris is mainly dispersed in the vertical direction.

In this case, the upper side of the IGBT 500 is coupled to and supported by the heat-dissipating body 410, and the lower side of the IGBT 500 is surrounded by the capacitor member 700. Accordingly, even in the event of an explosion of the IGBT 500, the scattering of debris can be minimized. As a result, even without the provision of a separate component for improving explosion-proof performance, the explosion-proof performance of the sub-module 10 can be enhanced.

In the embodiment illustrated in FIG. 14, the capacitor member 700 includes a capacitor body 710, a capacitor terminal 720, and a capacitor fastening hole 730.

The capacitor body 710 forms the outer shape of the capacitor member 700. A space is formed inside the capacitor body 710 to accommodate the capacitor element (not shown).

The capacitor body 710 surrounds the IGBT-accommodating part 450 from the other side in the height direction—specifically, from the lower side in the illustrated embodiment. The capacitor body 710 supports the output busbar 620 and the IGBT 500 coupled thereto from below.

The capacitor body 710 may be formed in a shape corresponding to the shape of the IGBT 500. As described above, a plurality of IGBTs 500 may be provided. The capacitor body 710 may be arranged to overlap with the plurality of IGBTs 500 in the height direction, which is the vertical direction in the illustrated embodiment. In the illustrated embodiment, the area of the capacitor body 710 in the horizontal direction may be greater than the total area of the plurality of IGBTs 500 in the horizontal direction.

In the illustrated embodiment, the capacitor body 710 has a rectangular cross-section and is formed in the shape of a rectangular pillar having a height in the vertical direction.

The capacitor body 710 is coupled to the heat-dissipating support part 440. In the illustrated embodiment, the heat-dissipating support part 440 is coupled to the inner side of each corner of the capacitor body 710. To facilitate coupling with the heat-dissipating support part 440, grooves (not shown) may be recessed in the upper surface of the capacitor body 710.

One surface of the capacitor body 710 that faces the IGBT 500—specifically, the upper surface in the illustrated embodiment—is provided with the capacitor terminal 720.

The capacitor terminal 720 is a portion through which the capacitor member 700 is electrically connected to the outside. The capacitor terminal 720 is coupled to and conducts electricity with the output busbar 620. Accordingly, the capacitor terminal 720 can be electrically connected to the IGBT 500.

The capacitor terminal 720 is coupled to the capacitor body 710. The capacitor terminal 720 is electrically connected to a capacitor element (not shown) located inside the capacitor body 710.

The capacitor terminal 720 may have a shape corresponding to the shape of the output busbar 620. In the illustrated embodiment, the capacitor terminal 720 is provided in a rectangular plate shape having a length in the front-rear direction, a width in the left-right direction, and a height in the vertical direction.

The capacitor terminal 720 may be disposed at a position corresponding to the position of the output busbar 620. In addition, a plurality of capacitor terminals 720 may be provided and may be coupled to and conduct electricity with the respective plurality of output busbars 620.

In the illustrated embodiment, the capacitor terminal 720 includes a first capacitor terminal 721 and a second capacitor terminal 722.

The first capacitor terminal 721 is coupled to and conducts electricity with the first output busbar 621. The first capacitor terminal 721 electrically connects the capacitor member 700 to the first output busbar 621 and the first and third IGBTs 510 and 530 coupled thereto.

The first capacitor terminal 721 may be disposed at a position corresponding to the shape and position of the second extension portion 621b of the first output busbar 621. In the illustrated embodiment, the first capacitor terminal 721 is positioned closer to one side in the width direction of the capacitor body 710, that is, the left side.

The second capacitor terminal 722 is coupled to and conducts electricity with the second output busbar 622. The second capacitor terminal 722 electrically connects the capacitor member 700 to the second output busbar 622 and to the second and fourth IGBTs 520 and 540 coupled thereto.

The second capacitor terminal 722 may be disposed at a position corresponding to the shape and position of the second extension portion 622b of the second output busbar 622. In the illustrated embodiment, the second capacitor terminal 722 is positioned closer to the other side in the width direction of the capacitor body 710, that is, the right side.

A capacitor fastening hole 730 is formed to penetrate through the interior of the capacitor terminal 720.

The capacitor fastening hole 730 is a space through which the capacitor fastening member 660 passes. The capacitor fastening hole 730 is formed to penetrate through the interior of the capacitor terminal 720 in the thickness direction of the capacitor terminal 720, which is the left-right direction in the illustrated embodiment.

The capacitor fastening hole 730 may be arranged to align with the through holes formed in the second extension portions 621b and 622b of the output busbar 620. The capacitor fastening member 660 may be inserted through and coupled to the through holes and the capacitor fastening hole 730, respectively.

A plurality of capacitor fastening holes 730 may be formed. Some of the plurality of capacitor fastening holes 730 may be formed in the first capacitor terminal 721. The remaining capacitor fastening holes 730 may be formed in the second capacitor terminal 722.

In the illustrated embodiment, the capacitor fastening hole 730 includes a first capacitor fastening hole 731 formed in the first capacitor terminal 721 and a second capacitor fastening hole 732 formed in the second capacitor terminal 722.

The first capacitor fastening hole 731 is coupled to the first capacitor fastening member 661. A plurality of first capacitor fastening holes 731 may be provided and may be spaced apart from one another in the extension direction of the first capacitor terminal 721, which is the front-rear direction in the illustrated embodiment. In the illustrated embodiment, six first capacitor fastening holes 731 are formed and are arranged to be spaced apart from one another in the front-rear direction.

The number and arrangement of the first capacitor fastening holes 731 may vary depending on the number and arrangement of the through holes formed in the second extension portion 621b of the first output busbar 621.

The second capacitor fastening hole 732 is coupled to the second capacitor fastening member 662. A plurality of second capacitor fastening holes 732 may be provided and may be spaced apart from one another in the extension direction of the second capacitor terminal 722, which is the front-rear direction in the illustrated embodiment. In the illustrated embodiment, six second capacitor fastening holes 732 are formed and are arranged to be spaced apart from one another in the front-rear direction.

### 3. Description of the Coupled State of the Sub-Module 10 According to an Embodiment of the Present Disclosure

The sub-module 10 according to an embodiment of the present disclosure can improve the explosion-proof effect of the IGBT 500 without requiring a separate component dedicated to explosion protection.

Specifically, debris generated in the event of an explosion of the IGBT 500 is primarily scattered in the surface direction of the IGBT 500. Accordingly, in the sub-module 10 according to an embodiment of the present disclosure, the surface of the IGBT 500 is arranged to be positioned horizontally, and the other components of the sub-module 10 are stacked above or below the IGBT 500 in the height direction, that is, the vertical direction.

In this case, the upper surface of the IGBT 500 is coupled to the heat-dissipating body 410 of the heat-dissipating member 400. Accordingly, scattering of debris upward in the event of an explosion of the IGBT 500 can be prevented by the heat-dissipating body 410.

In addition, the lower surface of the IGBT 500 is arranged to face the capacitor body 710. Accordingly, in the event of an explosion of the IGBT 500, the scattering of debris downward can also be prevented by the capacitor body 710.

Therefore, scattering of debris generated in the event of an explosion of the IGBT 500 can be prevented without providing a separate component dedicated to explosion protection. Accordingly, the explosion-proof performance of the sub-module 10 can be improved.

In addition, since a separate component dedicated to explosion protection is not required, the number of components of the sub-module 10 and the number of portions where the components are coupled can also be reduced. Accordingly, assembly convenience can be improved, manufacturing cost and time can be reduced, and coupling reliability can be enhanced.

Furthermore, as each component of the sub-module 10 is stacked in the height direction, that is, the vertical direction, the amount of space occupied by the sub-module 10 in the horizontal direction can be reduced. Accordingly, the number of sub-modules 10 that can be accommodated within the same space may increase, thereby improving the layout flexibility of the sub-module 10 as well as the configuration flexibility of the modular multilevel converter composed of the sub-modules 10.

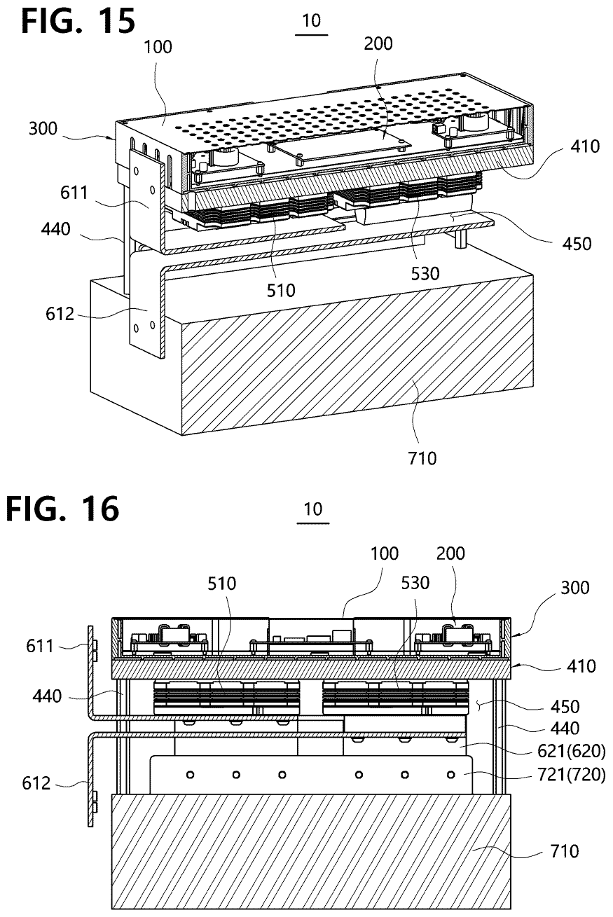

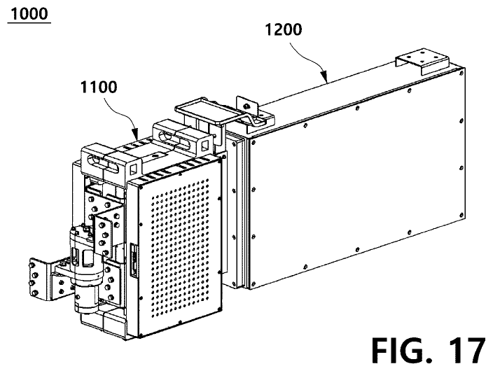

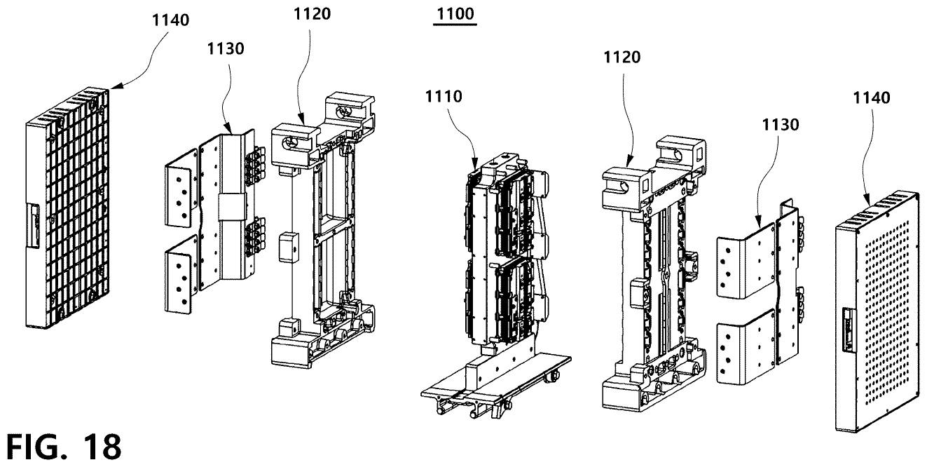

Hereinafter, with reference to FIGS. 15 and 16, a detailed description will be given of the coupled state of the sub-module 10 according to an embodiment of the present disclosure.

First, the board member 200 is accommodated in the housing space 320 of the housing member 300. The board member 200 accommodated in the housing space 320 is covered by the cover member 100, thereby blocking any unintended communication with the outside. In this case, heat generated from the board member 200 may be discharged to the outside of the housing space 320 through the cover communication hole 120.

In addition, the housing member 300 is supported by the heat-dissipating body 410. The heat-dissipating body 410 is provided in a plate shape, and the housing member 300 is seated on and supported by one surface of the heat-dissipating body 410 facing the housing member 300, that is, the upper surface in the illustrated embodiment.

The other surface of the heat-dissipating body 410 facing the capacitor member 700—specifically, the lower surface in the illustrated embodiment—is coupled to the IGBT 500. The heat-dissipating body 410 is configured to exchange heat with the IGBT 500 and cool the IGBT 500.

In this case, the heat-dissipating body 410 is formed to have a surface area greater than the total area of the upper surfaces of the plurality of IGBTs 500 that face the heat-dissipating body 410—specifically, the upper surface in the illustrated embodiment. Accordingly, all of the plurality of IGBTs 500 are arranged to be covered by the heat-dissipating body 410.

Accordingly, in the event of an explosion of the IGBT 500, debris generated by the explosion is prevented from moving upward by the heat-dissipating body 410.

The other surface of the IGBT 500 facing the capacitor member 700—specifically, the lower surface in the illustrated embodiment—is coupled to the busbar member 600. In this case, the plurality of IGBTs 500 are coupled to one or more different components provided in the busbar member 600, respectively.

That is, the first IGBT 510 is coupled to the first input busbar 611 and the first output busbar 621, and the second IGBT 520 is coupled to the first input busbar 611 and the second output busbar 622. The third IGBT 530 is coupled to the second input busbar 612 and the first output busbar 621, and the fourth IGBT 540 is respectively coupled to the second input busbar 612 and the second output busbar 622.

Accordingly, in the event of an explosion of the IGBT 500, debris generated by the explosion can be primarily blocked from moving downward by the busbar member 600.

In addition, the busbar member 600 is coupled to the capacitor member 700. The busbar member 600 is coupled to the capacitor terminal 720, which is coupled to the capacitor body 710. Accordingly, the capacitor body 710 can support the IGBT 500 and the busbar member 600 coupled thereto from below. The capacitor body 710 surrounds the IGBT 500 and the IGBT-accommodating part 450 that accommodates the IGBT 500 from the lower side.

Accordingly, in the event of an explosion of the IGBT 500, debris generated by the explosion can be secondarily blocked from moving downward by the capacitor body 710.

Accordingly, even without a separate component for explosion protection, the explosion-proof performance of the sub-module 10 can be ensured by the heat-dissipating body 410 and the capacitor body 710. In addition, as each component of the sub-module 10 is stacked in the height direction, the space occupied by the sub-module 10 can be reduced.

Although exemplary embodiments of the present disclosure have been described, the spirit of the present disclosure is not limited to the embodiments set forth herein. Those of ordinary skill in the art who understand the spirit of the present disclosure may easily propose other embodiments through supplement, change, removal, addition, etc. of elements within the scope of the same inventive concept, but such embodiments will also fall within the scope of the present disclosure.

| | |
|---|---|
| 10: sub-module | 100: cover member |
| 110: cover body | 120: cover communication hole |
| 200: board member | 210: board body |
| 220: input module | 230: output module |
| 240: partition member | 250: board communication hole |
| 300: housing member | 310: housing body |
| 311: first housing surface | 312: second housing surface |
| 320: housing space | 330: housing opening |
| 400: heat-dissipating member | 410: heat-dissipating body |
| 420: heat-dissipating | 430: heat-dissipating cap |
| communication part | |
| 440: heat-dissipating support | 450: IGBT-accommodating part |
| part | |
| 500: IGBT | 510: first IGBT |
| 520: second IGBT | 530: third IGBT |
| 540: fourth IGBT | 600: busbar member |
| 610: input busbar | 611: first input busbar |
| 612: second input busbar | 620: output busbar |
| 621: first output busbar | 621a: first extension portion |
| 621b: second extension portion | 622: second output busbar |
| 622a: first extension portion | 622b: second extension portion |
| 630: input fastening member | 631: first input fastening |
| | member |
| 632: second input fastening | 640: output fastening member |
| member | |
| 641: first output fastening | 642: second output fastening |
| member | member |
| 650: support member | 660: capacitor fastening member |
| 661: first capacitor fastening | 662: second capacitor fastening |
| member | member |
| 700: capacitor member | 710: capacitor body |
| 720: capacitor terminal | 721: first capacitor terminal |
| 722: second capacitor terminal | 730: capacitor fastening hole |
| 731: first capacitor fastening | 732: second capacitor fastening |
| hole | hole |
| 1000: sub-module according to | 1100: power assembly |
| the related art | |
| 1110: IGBT part | 1120: explosion-proof part |
| 1130: busbar part | 1140: cover part |
| 1200: capacitor assembly | |

1. A sub-module, comprising:
an insulated gate bipolar transistor (IGBT) that is electrically connectable to an external power source or load and has a surface area in one direction greater than that of a surface in another direction;
a heat-dissipating member coupled to one surface of the IGBT in the one direction to cool heat generated from the IGBT; and
a capacitor member that is electrically connected to the IGBT and is disposed to face the other surface of the IGBT in the one direction,
wherein the heat-dissipating member comprises:
a heat-dissipating body coupled to the one surface of the IGBT in the one direction;
a heat-dissipating support part that continuously extends between the heat-dissipating body and the capacitor member and is coupled to each of the heat-dissipating body and the capacitor member; and
an IGBT-accommodating part that is defined by being partially surrounded by the heat-dissipating body and the capacitor member, and accommodates the IGBT.

2. The sub-module of claim 1, wherein the heat-dissipating body has a surface, which faces the IGBT, the surface area of which is greater than that of the one surface of the IGBT in the one direction.

3. The sub-module of claim 2,
wherein a plurality of IGBTs are provided, the plurality of IGBTs being spaced apart from one another in a width direction and a length direction of the heat-dissipating body,
and the heat-dissipating body is formed to cover all of the plurality of IGBTs along the one direction.

4. The sub-module of claim 1,
further comprising:
a busbar member that is accommodated in the IGBT-accommodating part and electrically connected to each of the IGBT and the capacitor member,
wherein the capacitor member comprises:
a capacitor body that is coupled to the heat-dissipating support part and surrounds the IGBT-accommodating part from one side; and
a capacitor terminal that is coupled to the capacitor body and electrically coupled to the busbar member.

5. The sub-module of claim 4,
wherein the busbar member comprises:
an input busbar that is electrically coupled to each of the IGBT and an external power source or load; and
an output busbar that is electrically coupled to each of the IGBT and the capacitor terminal.

6. The sub-module of claim 5,
wherein a plurality of IGBTs are provided, the plurality of IGBTs being spaced apart from one another in a width direction and a length direction of the heat-dissipating body,
and the input busbar comprises:
a first input busbar that is electrically coupled to some of the plurality of IGBTs and to an external power source or load, respectively; and
a second input busbar that is spaced apart from the first input busbar and is electrically coupled to the other some of the plurality of IGBTs and to an external power source or load, respectively.

7. The sub-module of claim 6,
wherein the second input busbar is disposed closer to the capacitor member along the one direction than the first input busbar,
and the busbar member comprises:
a support member that is positioned between the other surface of the IGBT and the second input busbar and is electrically coupled to each of the IGBT and the second input busbar.

8. The sub-module of claim 5,
wherein a plurality of IGBTs are provided, the plurality of IGBTs being spaced apart from one another in a width direction and a length direction of the heat-dissipating body,
a plurality of capacitor terminals are provided, the plurality of capacitor terminals being spaced apart from one another in the width direction of the heat-dissipating body,
and the output busbar comprises:
a first output busbar that is electrically coupled to some of the plurality of IGBTs and to one of the plurality of capacitor terminals, respectively; and
a second output busbar that is electrically coupled to the other some of the plurality of IGBTs and to another one of the plurality of capacitor terminals, respectively.

9. The sub-module of claim 8,
wherein the output busbar comprises:
a first extension portion that extends in a length direction of the heat-dissipating body and is electrically coupled to a plurality of the IGBTs that are spaced apart from one another in the length direction of the heat-dissipating body; and
a second extension portion that is continuous with the first extension portion and extends in the length direction and a height direction of the heat-dissipating body and is electrically coupled to the capacitor terminal.

10. The sub-module of claim 4, wherein a surface area of one surface of the capacitor body that faces the IGBT is greater than a surface area of one surface of the IGBT that faces the capacitor body.

11. The sub-module of claim 4, wherein the capacitor member, the busbar member, the IGBT, and the heat-dissipating member are sequentially stacked along a height direction.

12. The sub-module of claim 1,
further comprising:
a housing member that is disposed to face the IGBT with the heat-dissipating member interposed therebetween and is coupled to and supported by the heat-dissipating member;
a board member that is accommodated in a housing space formed inside the housing member and is electrically connectable to the outside; and
a cover member that covers the board member and is coupled to the housing member.

13. The sub-module of claim 12,
wherein the housing member comprises:
a housing surface that surrounds the housing space in an outer circumferential direction; and
a housing opening that is formed through the housing surface to allow communication between the housing space and the outside,
and the board member comprises:
an input module that is electrically connectable to the outside;
a board body coupled to the input module and supporting the input module;
a partition member extending along an outer circumference of the board body; and
a board communication hole formed through the partition member to communicate with the housing opening.

14. The sub-module of claim 12,
wherein the cover member comprises:
a cover body that covers the board member; and
a cover communication hole formed through the cover body to allow communication between the housing space and the outside.
